(19) United States
(12) Patent Application Publication
(10) Pub. No.: US 2022/0344686 A1
(43) Pub. Date: Oct. 27, 2022

(54) FUEL CELL STACK INSULATION MONITORING SYSTEM

(71) Applicant: Ceres Intellectual Property Company Limited, Horsham West Sussex (GB)

(72) Inventor: Lei Sun, Weifang, Shandong (CN)

(21) Appl. No.: 17/764,531

(22) PCT Filed: Sep. 30, 2020
(86) PCT No.: PCT/IB2020/059159

§ 371 Date: Mar. 28, 2022

(30) Foreign Application Priority Data
Sep. 30, 2019 (CN) 201921663423.6

(51) Int. Cl. H01M 8/04537; H01M 8/04664; B60L 3/00; G01R 27/02; G01R 31/56

(52) U.S. Cl. CPC H01M 8/04649; H01M 8/04679; B60L 3/0046; G01R 27/025; G01R 31/56; H01M 2250/20

(57) ABSTRACT

The present application provides a stack module fault monitoring system, comprising an insulation resistance tester; a stack module, which consists of m groups of stack strings; m electronic switch groups, wherein each electronic switch group comprises a first switch and a second switch; one end of the first switch is connected with positive electrodes of one group of stack strings, and the other end of the first switch is connected with a positive electrode end of the insulation resistance tester; one end of the second switch is connected with negative electrodes of the group of stack strings, and the other end of the second switch is connected with a negative electrode end of the insulation resistance tester; a control end of a switch in the electronic switch group is connected with a controller, and the switch in the electronic switch group is controlled to be on and off by the controller; the insulation resistance tester tests the insulation resistance of each group of stack strings in sequence and sends the insulation resistance to the controller; the controller determines whether the group of stack strings has then insulation fault or not according to the insulation resistance, so as to realize online monitoring on whether each group of stack strings has the insulation fault or not, and quickly position the stack string with the insulation fault in the stack module.

### TECHNICAL FIELD

The present invention belongs to the technical field of fuel cells, particularly to a stack module fault monitoring system and method.

### BACKGROUND ART

The stack module is used for supplying power to the fuel cell electric vehicle. Each group of stack strings consists of a plurality of stacks.

At present, whether the whole stack module has the insulation fault or not can only be monitored on-line, and the whole stack module will shut down in case of the insulation fault. The stack module will be disassembled, and then the insulation resistance of each group of stack strings in the stack module is tested in sequence. Which group of stack strings has the insulation fault is determined according to the insulation resistance of each group of stack strings, in order to realize fault positioning.

The existing monitoring method for stack module insulation faults cannot monitor on-line whether each set of stack strings in the stack module has any insulation faults, so that it is difficult to position the faults in the stack module.

### SUMMARY OF THE INVENTION

The present invention provides a stack module fault monitoring system to solve the problem that the prior art cannot monitor on-line whether each set of stack strings in the stack module has any insulation faults so that it is difficult to position the faulted stack in the stack module.

The present invention provides a stack module fault monitoring system, comprising an insulation resistance tester; a stack module, wherein the stack module has m groups of stack strings, and m is a positive integer greater than or equal to 1; and m electronic switch groups; wherein each of the electronic switch groups has a first switch and a second switch; a first end of the first switch is connected with positive electrodes of one group of stack strings, and a second end of the first switch is connected with a positive electrode end of the insulation resistance tester. The first end of the second switch is connected with the negative electrode of this set of stack strings and the second end of the second switch is connected with the negative electrode end of the insulation resistance tester. A controller is connected with a control end of the first switch and a control end of the second switch, respectively; the controller controls the switch in the electronic switch group to be on and off. The insulation resistance tester detects the insulation of each set of stack strings in sequence and sends the detected insulation resistance to the controller connected with the insulation resistance tester to monitor whether each set of stack strings in the stack module has any insulation faults.

The system can also comprise a stack precharging unit wherein the positive electrode of the DC bus of the stack precharging unit is connected with the positive electrode of each set of stack strings; the negative electrode of the DC bus bar of the stack precharging unit is connected with the negative electrode of each group of stack strings.

The system can also comprise a first diode and a second diode respectively connected to each group of stacks in series wherein the anode of the first diode is connected with the positive electrode of each group of stack strings, and the cathode of the first diode is connected with the positive electrode of the DC bus of the stack precharging unit; the anode of the second diode is connected with the negative electrode of the DC bus of the stack precharging unit, and the cathode of the second diode is connected with the negative electrode of each group of stack strings.

The system can also comprise m power switches wherein the control end of each power switch is respectively connected with the controller. The opening and closing of the power switch is controlled by the controller. The connection between the positive electrode of the DC bus bar of the stack precharging unit and the positive electrode of each group of stack strings comprises the following steps: the first end of each power switch is connected with the positive electrode of a group of stack strings, and the second end of each power switch is connected with the positive electrode of the DC bus of the stack precharging unit.

The insulation resistance tester can be connected with the controller via a CAN bus. The tested insulation resistance can be sent to the controller connected with the insulation resistance tester to monitor whether each group of stack strings in the stack module has an insulation fault or not, wherein the insulation resistance detected is sent to the controller via a CAN bus to monitor whether each set of stack strings in the stack module has any insulation faults by the controller.

The electronic switch group can be the isolated power electronics.

The present invention provides a stack module fault monitoring system, which comprises an insulation resistance tester; a stack module, comprising m sets of stack strings; m electronic switch groups, wherein each electronic switch group comprises a first switch and a second switch. One end of the first switch is connected with the positive electrode of a set of stack strings and the other end of the first switch is connected with the positive electrode end of the insulation resistance tester; one end of the second switch is connected with the negative electrode of this set of stack strings, and the other end of the second switch is connected with the negative electrode end of the insulation resistance tester; a control end of a switch in the electronic switch group is connected with a controller, and the controller is used to control the switching-on or switching-off of the switch in the electronic switch group, so that the insulation resistance tester detects the insulation resistance of each set of stack strings in sequence and sends the insulation resistance to the controller; the controller determines whether this set of stack strings has any insulation faults according to the insulation resistance, so as to online monitor whether each set of stack strings has any insulation faults and quickly position the stack string with an insulation fault in the stack module.

The invention also provides a stack module fault monitoring method for use with a monitoring system comprising an insulation resistance tester, a stack module comprising m groups of stack strings, wherein m is a positive integer greater than or equal to 1, in electronic switch groups, wherein each of the electronic switch groups comprises a first switch and a second switch, wherein a first end of the first switch is connected with positive electrodes of one group of stack strings, and a second end of the first switch is connected with a positive electrode end of the insulation resistance tester, and a first end of the second switch is connected with negative electrodes of the group of stack strings, and a second end of the second switch is connected with a negative electrode end of the insulation resistance tester, and a controller connected with a control end of the first switch and a control end of the second switch, respectively; the controller controls the switch in the electronic switch group to be on and off; the method comprising testing, by means of the insulation resistance tester, the insulation resistance of each group of stack strings in sequence, and sending the tested insulation resistance to the controller connected with the insulation resistance tester, and determining whether each group of stack strings in the stack module has an insulation fault or not.

### BRIEF DESCRIPTION OF THE DRAWING

The drawings used in the description will be briefly described below. The drawings in the description below are some embodiments of the present invention.

FIG. 1 is a structural schematic view of a stack module fault monitoring system.

FIG. 2 is another structural schematic view of a stack module fault monitoring system.

### DESCRIPTION OF EMBODIMENTS

Embodiments of the present invention will be described below in conjunction with the drawings. The described embodiments are only some, not all of the embodiments of the present invention.

The present embodiment provides a stack module fault monitoring system. This stack module fault monitoring system can on-line monitor whether each set of stack strings in the stack module has any insulation faults and can quickly and simply position a stack string with an insulation fault in the stack module.

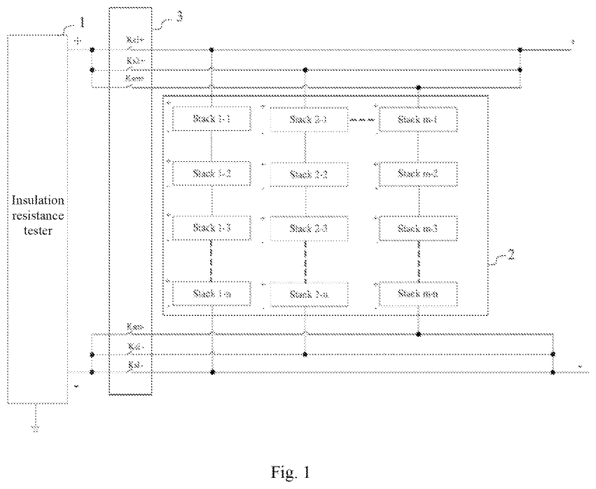

As shown in FIG. 1, the stack module fault monitoring system in the present embodiment comprises an insulation resistance tester 1, and a stack module 2, wherein the stack module 2 comprises m sets of stack strings, where m is a positive integer equal to or greater than 1.

Each set of stack strings is composed of n stacks, where n is a positive integer equal to or greater than 1. Parallel connection is made between stack strings and serial connection is made between stacks in each set of stack strings.

There are m electronic switch groups 3, and one of the electronic switch groups is separately connected with one set of stack strings and the insulation resistance tester 1, i.e. each set of stack strings are separately connected with insulation resistance tester 1 via one electronic switch group.

The structure of connection among electronic switch groups 3, stack strings and insulation resistance tester 1 is as follows:

Each electronic switch group comprises a first switch and a second switch. A first end of the first switch is connected with the positive electrode of one set of stack strings and a second end of the first switch is connected with the positive electrode end of insulation resistance tester 1. A first end of the second switch is connected with the negative electrode of this set of stack strings and a second end of the second switch is connected with the negative electrode end of insulation resistance tester 1.

For each electronic switch group, a control end of the first switch and a control of the second switch in this electronic switch group are connected with a controller. The controller is not shown in FIG. 1.

The controller controls the switching-off and switching-on of the first switch and the second switch in each electronic switch group, and the first switch and the second switch in each electronic switch group are synchronously switched off and on.

For an electronic switch group, when the first switch and the second switch in this electronic switch group are switched on, the stack string connected with this electronic switch group is connected with the insulation resistance tester. In this case, the insulation resistance tester detects the insulation resistance of this stack string.

Taking the connection of the first electronic switch group with the first set of stack strings and insulation resistance tester 1 as an example, when the first switch and the second switch in the first electronic switch group are synchronously switched on, a closed loop is formed between the first set of stack strings and insulation resistance tester 1, so that insulation resistance tester 1 can be used to detect the insulation resistance of the first set of stack strings. In this case, the first switches and the second switches in other m-1 electronic switch groups are switched off to disconnect the stack strings in other m-1 groups from insulation resistance tester 1.

Based on this, insulation resistance tester 1 can detect the insulation resistance of each set of stack strings in sequence. And, the principle that insulation resistance tester 1 detects the insulation resistance is the same as the principle of insulation resistance testing in the prior art, so it will not be described again.

Optionally, the switches in the electronic switch group in this embodiment are isolated power electronics, e.g. MOS tube, IGBT or silicon carbide tube. Namely, the first switch is one of MOS tube, IGBT or carborundum tube and the second switch is also one of MOS tube, IGBT or silicon carbide tube.

The insulation resistance tester 1 sends the detected insulation resistance of each set of stack strings to the controller connected with insulation resistance tester 1. Based on the insulation resistance, the controller can determine whether this set of stack strings has any insulation faults so as to on-line detect whether each set of stack strings in the stack have any insulation faults and position the stack string with an insulation fault in the stack module.

In this embodiment, the controller can be the FCU, insulation resistance tester 1 can be connected with the controller via a CAN bus, and after insulation resistance tester 1 detects the insulation resistance of stack strings, it sends the insulation resistance detected to the controller via the CAN bus.

The stack module fault monitoring system in this embodiment comprises an insulation resistance tester, a stack module comprising m sets of stack strings, m electronic switch groups wherein each of the electronic switch groups comprises a first switch and a second switch, and a first end of the first switch is connected with the positive electrode of one set of stack strings, a second end of the first switch is connected with the positive electrode end of an insulation resistance tester, a first end of the second switch is connected with the negative electrode of this set of stack strings, and a second end of the second switch is connected with the negative electrode end of the insulation resistance tester; and a control separately connected with a control end of the first switch and a control end of the second switch. The controller can control the switching-off and switching-on of switches in an electronic switch group to connect each set of stack strings with an insulation resistance tester in sequence, and the insulation resistance tester detects the insulation resistance of this set of stack strings connected with the insulation resistance tester and send the insulation resistance to the controller to monitor whether each set of stack strings in a stack module has any insulation faults, so as to on-line monitor whether each set of stack strings in the stack module and position has any insulation faults and position a stack string with an insulation fault in the stack module.

A stack module is used for providing power for a fuel cell electric vehicle. For example, the stack module is connected with a stack precharging unit of the electric vehicle, the stack precharging unit is connected with the DC bus of the electric vehicle, and power is supplied to the electric vehicle through the stack precharging unit.

However, in the process of on-line monitoring of any insulation defects in a stack module, the stack module is not required to separately removed, so the stack module fault monitoring system provided in the present application also comprises a stack precharging unit. A positive electrode of the DC bus of a stack precharging unit is connected with the positive electrode of each set of stack strings. The negative electrode of the DC bus of the stack precharging unit is connected with the negative electrode of each set of stack strings to realize the power supply for the electric vehicle with a fuel cell stack via the stack precharging unit.

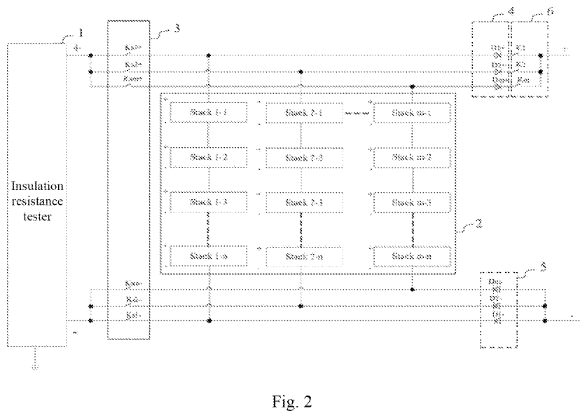

On the basis that a stack precharging unit is included, as shown in FIG. 2, the stack module fault monitoring system in this embodiment also comprises, based on FIG. 1, a first diode 4 and a second diode 5 separately connected with each set of stack strings. The positive electrode of the first diode 4 is connected with the positive electrode of each set of stack strings, and the negative electrode of the first diode 4 is connected with the positive electrode of the DC bus of the stack precharging unit; the positive electrode of the second diode 5 is connected with the negative electrode of the DC bus of the stack precharging unit, and the negative electrode of the second diode 5 is connected with the negative electrode of each set of stack strings. The direction of each of the first diodes 4 and each of the second diodes 5 in this embodiment is consistent with the direction of current when this stack string supplies power for the stack precharging unit.

Optionally, the first diode 4 and the second diode 5 may be power diodes. In this embodiment, the first diode 4 is set on the positive electrode of each set of stack strings and the second diode 5 is set on the negative electrode of each set of stack strings so as to isolate the positive electrode from the negative electrode of different stack strings and avoid the mutual interference caused by voltage imbalance of different stack strings.

As shown in FIG. 2, the stack module fault monitoring system in this embodiment also comprises m power switches 6.

A control end of each power switch is separately connected to the controller. The opening and closing of the power switch is controlled by the controller. The first end of each power switch is connected with the positive electrode of a group of stack strings, and the second end of each power switch is connected with the positive electrode of the DC bus of the stack precharging unit.

In this embodiment, one power switch is set at the DC bus output interface of each set of stack strings to control the switching-on or switching-off of each stack strings and the connection with the main DC bus, respectively. When the insulation resistance failure of a certain set of stack strings is detected, the controller can control the switching-off and switching-on of the corresponding power switch connected with this set of stack strings and cut the connection between the stack strings with an insulation failure and the DC bus to prevent the stack strings from further suffering insulation failures and also ensure that the whole vehicle operates in the extended range mode while other normal stack strings operate.

Based on the foregoing technical solutions, the stack module fault monitoring system provided in this embodiment can realize the on-line monitoring of independent insulation resistance of each set of stack strings in a stack module, eliminate the impact of power diodes on the testing results when the insulation resistance testing is performed for the whole stack module, and improve the accuracy of insulation resistance testing results of the stack module. And, when the insulation resistance failure of a certain set of stack strings is determined, a faulted stack string can be accurately positioned and the controller can control the disconnection with the faulted stack string and the connection with the DC bus to ensure the operation of normal stack strings and effectively improve the safety and reliability of the vehicle system powered up by the stack module.

By reference to the stack module fault monitoring system shown in FIG. 2, a first set of stack strings comprises n stack strings connected in series, e.g. Stack1-1, Stack1-2, . . . Stack1-n. The first set of stack strings is connected with the first electronic switch group. The first electronic switch group is used to realize the connection between the first set of stack strings and the insulation resistance tester, and the first switch group shown in FIG. 2 comprises a first switch Ks1+ and a second switch Ks1−. The positive electrode of the first set of stack strings, i.e. positive electrode of Stack1-1, is connected with the first switch Ks1+ and connected with the positive electrode of the insulation resistance tester via the first switch Ks1+. The negative electrode of the first set of stack strings, i.e. negative electrode of Stack1-n, is connected with the first switch Ks1− and connected with the negative electrode of the insulation resistance tester via the first switch Ks1−.

The positive electrode of the first set of stack strings, i.e. positive electrode of Stack1-1, is connected with the first diode D1+, and the negative electrode of the first set of stack strings, i.e. negative electrode of Stack1-n, is connected with the second diode D1−.

The positive electrode of the first set of stack strings, i.e. positive electrode of Stack1-1, is connected with the first power switch K1, and the second end of the first power switch K1 is connected with the positive electrode of the DC bus of the stack precharging unit.

Similarly, the ith set of stack strings comprises n stack strings connected in series, e.g. Stacki-1, Stacki-2, Stacki-n. i is a positive integer ranging from 1 to m.

The ith set of stack strings is connected with the ith electronic switch group. The ith electronic switch group is used to realize the connection between the ith set of stack strings and the insulation resistance tester, and the ith electronic switch group shown in FIG. 2 comprises a first switch Ksi+ and a second switch Ksi−. The positive electrode of the ith set of stack strings, i.e. positive electrode of Stacki-1, is connected with the first switch Ksi+ and connected with the positive electrode of the insulation resistance tester via the first switch Ksi+. The negative electrode of the ith set of stack strings, i.e. negative electrode of Stacki-n, is connected with the first switch Ksi− and connected with the negative electrode of the insulation resistance tester via the first switch Ksi−.

The positive electrode of the ith set of stack strings, i.e. positive electrode of Stacki-1, is connected with the first diode Di+, and the negative electrode of the ith set of stack strings, i.e. negative electrode of Stacki-n, is connected with the second diode Di−.

The positive electrode of the ith set of stack strings, i.e. positive electrode of Stacki-1, is connected with the first end of the ith power switch Ki, and the second end of the ith power switch Ki is connected with the positive electrode of the DC bus of the stack precharging unit.

Based on the stack module fault monitoring system shown in FIG. 2, the working principle of the stack module fault monitoring system is described by taking insulation resistance testing for the first set of stack strings as an example.

(1) During operation, the controller, e.g. FCU, controls the switching-on of m power switches (K1, K2 . . . Km) to connect the stack module with the DC bus of an electric vehicle and supply power for the extended range of the whole vehicle.

(2) The FCU controls the synchronous switching-on of two switches (Ks1+ and Ks1−) in the first electronic switch group and controls synchronous switching-off of Ksi+ and Ksi−(m≥i≥2) in other m-1 electronic switch groups except for those in the first electronic switch group, and the insulation resistance tester detects the insulation resistance of the first set of stack strings and sends the detected insulation resistance of the first stack strings to the FCU via the CAN bus.

(3) The FCU determines whether the first set of stack strings has any insulation faults according to the insulation resistance of the first stack string received and controls the switching-on and switching-off of K1 under the condition that an insulation fault of the first set of stack strings is determined, so as to cut the connection between the first set of stack strings and the DC bus and prevent the insulation fault from further deteriorating.

The foregoing steps are taken to detect the insulation resistance of the mth set of stack strings and on-line monitor whether each set of stack strings in the stack module has any insulation faults, and when a certain set of stack strings has an insulation fault, the stack string with an insulation fault can be accurately positioned and the stack strings controlled by the FCU is disconnected from the DC bus to ensure the operation of normal stack strings and effectively improve the safety and reliability of the vehicle system powered up by the stack module.

The embodiments in the Description are all described in a progressive manner and the same or similar parts among the embodiments can be mutually referred to, and each embodiment focuses on the differences from other embodiments.

The above is only one embodiment of the present invention, and improvements and embellishments can be made without departing from the principles of the present invention and within the scope of protection of the present invention.

1. A stack module fault monitoring system, wherein the monitoring system comprises:
an insulation resistance tester;
a stack module comprising m groups of stack strings, wherein m is a positive integer greater than or equal to 1;
m electronic switch groups, wherein each of the electronic switch groups comprises a first switch and a second switch, wherein:
a first end of the first switch is connected with positive electrodes of one group of stack strings, and a second end of the first switch is connected with a positive electrode end of the insulation resistance tester; and
a first end of the second switch is connected with negative electrodes of the group of stack strings, and a second end of the second switch is connected with a negative electrode end of the insulation resistance tester; and
a controller connected with a control end of the first switch and a control end of the second switch, respectively; the controller controls the switch in the electronic switch group to be on and off;
wherein the insulation resistance tester is configured to test the insulation resistance of each group of stack strings in sequence and to send the tested insulation resistance to the controller connected with the insulation resistance tester, in order to monitor whether each group of stack strings in the stack module has the insulation fault or not.

2. The monitoring system according to claim 1, wherein the monitoring system further comprises a stack precharging unit, wherein the positive electrode of the DC bus bar of the stack precharging unit is connected with the positive electrode of each group of stack strings, and the negative electrode of the DC bus bar of the stack precharging unit is connected with the negative electrode of each group of stack strings.

3. The monitoring system according to claim 2, wherein the monitoring system further comprises:
a first diode and a second diode respectively connected to each group of stack strings in series;
wherein an anode of the first diode is connected with the positive electrode of each group of stack strings, and a cathode of the first diode is connected with the positive electrode of the DC bus of the stack precharging unit; and
an anode of the second diode is connected with the negative electrode of the DC bus of the stack precharging unit, and a cathode of the second diode is connected with the negative electrode of each group of stack strings.

4. The monitoring system according to claim 2, wherein the monitoring system further comprises m power switches, wherein:
a control end of each power switch is respectively connected with the controller which is configured to control the opening and closing of the power switch; and
the connection between the positive electrode of the DC bus bar of the stack precharging unit and the positive electrode of each group of stack strings comprises:
a first end of each power switch connected with positive electrodes of one group of stack strings, and
a second end of each power switch connected with the positive electrode of the DC bus of the stack precharging unit.

5. The monitoring system according to claim 1, wherein the insulation resistance tester is connected to the controller through a CAN bus and is configured such that the step that the tested insulation resistance is sent to the controller connected with the insulation resistance tester to monitor whether each group of stack strings in the stack module has an insulation fault or not comprises sending the tested insulation resistance to the controller by the CAN bus to monitor whether each group of stack strings in the stack module has the insulation fault or not by the controller.

6. The monitoring system according to claim 1, wherein the electronic switch group is an isolated power electronic device.

7. A stack module fault monitoring method for use with a monitoring system comprising:
an insulation resistance tester;
a stack module comprising m groups of stack strings, wherein m is a positive integer greater than or equal to 1;
m electronic switch groups, wherein each of the electronic switch groups comprises a first switch and a second switch, wherein:
a first end of the first switch is connected with positive electrodes of one group of stack strings, and a second end of the first switch is connected with a positive electrode end of the insulation resistance tester; and
a first end of the second switch is connected with negative electrodes of the group of stack strings, and a second end of the second switch is connected with a negative electrode end of the insulation resistance tester; and
a controller connected with a control end of the first switch and a control end of the second switch, respectively; the controller controls the switch in the electronic switch group to be on and off;
the method comprising testing, by means of the insulation resistance tester, the insulation resistance of each group of stack strings in sequence, and sending the tested insulation resistance to the controller connected with the insulation resistance tester, and determining whether each group of stack strings in the stack module has an insulation fault or not.
